(19) United States
(12) Patent Application Publication
(10) Pub. No.: US 2026/0247777 A1
(43) Pub. Date: Aug. 20, 2026

(54) SUBSTRATE FOR MOUNTING, CONNECTING STRUCTURE, AND ELECTRONIC COMPONENT

(71) Applicant: TAIYO HOLDINGS CO., LTD., Saitama-ken (JP)

(72) Inventors: Kentaro OBUCHI, Saitama-ken (JP); Yasuaki ARAI, Saitama-ken (JP); Mariko SHIMAMIYA, Saitama-ken (JP); Satsuki OZAWA, Saitama-ken (JP)

(21) Appl. No.: 18/851,182

(22) PCT Filed: Mar. 28, 2023
(86) PCT No.: PCT/JP2023/012435

§ 371 Date: Sep. 26, 2024

(30) Foreign Application Priority Data
Mar. 30, 2022 (JP) 2022-057573

(51) Int. Cl. H10H 29/85; H10W 72/40

(52) U.S. Cl. CPC H10H 29/8508; H10W 72/40

(57) ABSTRACT

[Problem] Provided is a substrate for mounting, precluding poor connection caused by positional deviation even in the case of mounting a minute on-board component.
[Solution] The substrate for mounting according to the present invention is a substrate for mounting an on-board component. The substrate for mounting comprises a circuit board on which a plurality of electrodes are placed at a predetermined spacing, and a resin layer including a plurality of openings in the upper regions of the electrodes of the circuit board. In the substrate, in a case in which each opening of the resin layer has a size of X μm in a longitudinal direction and Y μm in a lateral direction, and the on-board component has a size of x μm in a longitudinal direction and y μm in a lateral direction, the following conditions: x+20<X<2x and y +20<Y<√(x²+y²) are satisfied.

### FIELD OF THE INVENTION

The present invention relates to a substrate for mounting. The present invention also relates to a connecting structure in which an on-board component is mounted on the substrate for mounting. The present invention further relates to an electronic component including the connecting structure.

### BACKGROUND ART

With the higher densities of printed wiring boards, caused by miniaturization of electronic instruments in recent years, development and improvement of conductive connection materials have been allowed to proceed for technologies used for electric connections between electronic components, for example, electric connections between wiring boards and electron devices, and electric connections between wiring boards. Such conductive connection materials enable electric connections with reduction in weight and savings in space by coating the conductive connection materials between members intended to be electrically connected, and heat-pressing the members. Specifically, although such a conductive connection material in itself has an insulation property, heat-pressing causes conductive particles contained in the conductive connection material to be sandwiched between and pressed against electrodes, to form a conductive pathway. As a result, the electrical connection between the members is enabled. In a region that is not sandwiched between the electrodes and is not pressurized even after the heat-pressing, conductive particles remain dispersed, and therefore the insulation property is maintained. As a result, so-called an anisotropically conductive connecting structure is formed (for example, Patent Literature 1 and the like).

Such an anisotropically conductive connection material that solder particles dispersed in a curable resin in a flow state are melted and self-assemble on an electrode by using such a property that an electrode attracts solder particles in a liquid resin in a case in which the solder particles are melted, solder can be placed only between electrodes intended to be connected, and an insulation property between the neighboring electrodes can be secured has also been developed (for example, Patent Literature 2 and the like). Such a type of anisotropically conductive connection material has been used in applications in which a plurality of electrodes are collectively electrically connected, such as COG mounting and FOG mounting.

In recent years, the downsizing of LED chips as on-board components has proceeded, and, for example, LED array substrates in which LED chips each having an outside dimension of around several tens of micrometers are mounted at an adjacent spacing of 1 mm or less on wiring substrates have also been put to practical use.

### CITATION LIST

### Patent Literature

[Patent Literature 1] Japanese Patent Laid-Open No. H8-003529
[Patent Literature 2] Japanese Patent Laid-Open No. 2016-127010

### SUMMARY OF THE INVENTION

### Technical Problem

In a case in which an on-board component such as a mini-LED or a μ-LED is mounted on a circuit board, the shapes of the openings of a resin layer formed in the upper region of an electrode in the circuit board are preferably formed without distinguishing between a plus-side PAD and a minus-side PAD in view of the easiness of formation of the openings. In a case in which the size of such an opening is equal to or smaller than the size of each LED, the LED is not put in the opening of the resin layer, and poor connection is prone to occur. In contrast, in a case in which the size of the opening is excessively larger than the size of the LED, the LED is very small for mounting, the position of the LED is prone to deviate in the opening of the resin layer, and poor connection may be prone to occur.

### Solution to Problem

As a result of intensive research, the present inventors found that in a substrate for mounting an on-board component, the substrate including a circuit board on which a plurality of electrodes are placed at predetermined spacings, and a resin layer including a plurality of openings in the upper regions of the electrodes of the circuit board, the problems described above can be solved by regulating the sizes of the openings of the resin layer and the size of the on-board component so that the sizes satisfy a specific condition. Thus, the present invention was accomplished.

In other words, in accordance with the present invention, the following invention is provided.
[1]A substrate for mounting an on-board component, the substrate for mounting, including a circuit board on which a plurality of electrodes are placed at a predetermined spacing, and a resin layer including a plurality of openings in upper regions of the electrodes of the circuit board, wherein
   in a case in which each opening of the resin layer has a size of X μm in a longitudinal direction and Y μm in a lateral direction, and the on-board component has a size of x μm in a longitudinal direction and y μm in a lateral direction, the following conditions:

$$x + 20 < X < 2 x and y + 20 < Y < \sqrt{( {x}^{2} + {y}^{2} )}$$

are satisfied.
[2] The substrate for mounting according to [1], wherein the resin layer has a thickness of 1 μm or more and 60 μm or less.
[3] The substrate for mounting according to [1] or [2], wherein the resin layer has at least any one of a white color and a black color.
[4] The substrate for mounting according to any of [1] to [3], wherein the resin layer is a solder resist layer.
[5] The substrate for mounting according to any of [1] to [4], wherein the on-board component is an LED.
[6]A connecting structure including: the substrate for mounting according to any of [1] to [5]; and the on-board component that is mounted in each opening of the substrate for mounting.
[7] The connecting structure according to [6], wherein the on-board component and the electrodes of the substrate for mounting are connected to each other through an anisotropically conductive connection material.
[8] The connecting structure according to [7], wherein the anisotropically conductive connection material comprises a thermosetting component (A), a polymerization initiator (B), and a solder particle (C).
[9] The connecting structure according to [7] or [8], wherein the anisotropically conductive connection material has a viscosity of 50 dPa·s or more and 3000 dPa·s or less at 25° C.
[10] An electronic component including the connecting structure according to any of [6] to [9].

### Advantageous Effects of Invention

In accordance with the present invention, a substrate for mounting, precluding poor connection caused by positional deviation even in the case of mounting a minute on-board component, can be provided. Moreover, in accordance with the present invention, a connecting structure in which an on-board component is mounted on the substrate for mounting can be provided. Further, in accordance with the present invention, an electronic component including the connecting structure can be provided.

### BRIEF DESCRIPTION OF THE DRAWINGS

FIG. 1 is a schematic cross-sectional view of a substrate for mounting of the present invention.

FIG. 2 is a schematic top view of the substrate for mounting of the present invention.

FIG. 3 is a schematic view of an on-board component that is mounted on a substrate for mounting of the present invention, from an electrode plane.

FIG. 4 is a schematic top view of a connecting structure of the present invention.

FIG. 5 is a diagrammatic schematic cross-sectional view of one example of a connecting structure of the present invention.

### DESCRIPTION OF EMBODIMENTS

### [Substrate for Mounting]

A substrate for mounting according to the present invention includes a circuit board on which a plurality of electrodes are placed at a predetermined spacing, and a resin layer including a plurality of openings in the upper regions of the electrodes of the circuit board.

In the present invention, the longitudinal and lateral directions of each opening of a resin layer are defined as follows. The longitudinal direction is regarded as a direction parallel to a side extending between a positive electrode and a negative electrode, and the lateral direction is regarded as a direction parallel to a side orthogonal to the longitudinal direction.

Moreover, the longitudinal and lateral directions of an on-board component are defined as follows. The longitudinal direction is regarded as a direction parallel to a side extending between a positive electrode and a negative electrode, and the lateral direction is regarded as a direction parallel to a side orthogonal to the longitudinal direction.

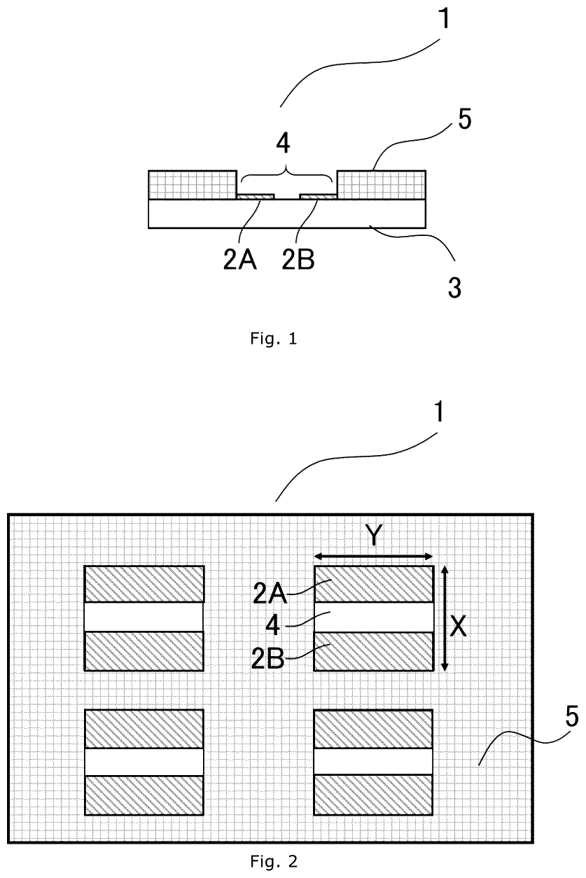

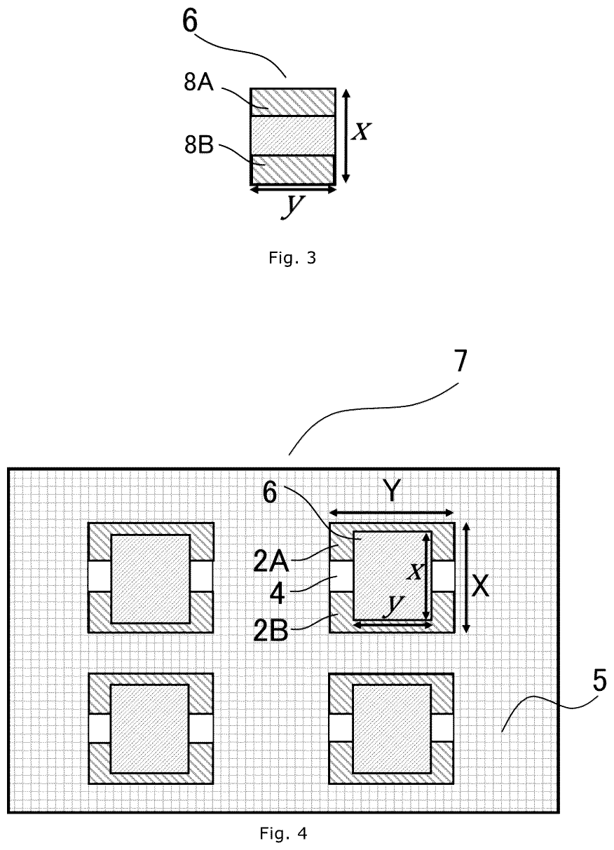

The substrate for mounting an LED according to the present invention is described with reference to the drawings. FIG. 1 illustrates a schematic cross-sectional view of a substrate for mounting. The substrate 1 for mounting illustrated in FIG. 1 includes a circuit board 3 on which a plurality of positive electrodes 2A and negative electrodes 2B are placed, and a resin layer 5 including a plurality of openings 4 in the upper regions of the electrodes 2. Moreover, FIG. 2 illustrates a schematic top view of the substrate for mounting. The resin layer 5, including the plurality of openings 4 for mounting an on-board component 6 in the upper regions of the electrodes 2, is disposed in the substrate 1 for mounting illustrated in FIG. 2. FIG. 3 illustrates a schematic view of the on-board component, from an electrode plane. The on-board component 6 illustrated in FIG. 3 includes a positive electrode 8A and a negative electrode 8B. Further, FIG. 4 illustrates a schematic top view of a connecting structure. In the connecting structure 7 illustrated in FIG. 4, on-board components 6 are mounted in the plurality of openings 4 of the resin layer 5. Here, it is illustrated that the length in the longitudinal direction of the size of each opening 4 is X, the length in the lateral direction of the size of each opening 4 is Y, the length in the longitudinal direction of the size of each on-board component 6 is x, and the length in the lateral direction of the size of each on-board component 6 is y.

### [Circuit Board]

A conventionally known circuit board can be used as the circuit board. Examples of the circuit board may include copper-clad laminates of all grades (such as FR-4) using materials such as copper-clad laminates for high-frequency circuits using paper phenol, paper epoxy, glass fabric epoxy, glass polyimide, glass fabric/nonwoven fabric epoxy, glass fabric/paper epoxy, synthetic fiber epoxy, fluorine resin/polyethylene/polyphenylene ether, polyphenylene oxide/cyanate, and the like, as well as printed wiring boards and flexible printed wiring boards on which circuits have been formed with copper and the like in advance, and, in addition, metal substrates, polyimide films, polyethylene terephthalate films, polyethylene naphthalate (PEN) films, glass substrates, ceramic substrates, and wafer plates.

On the circuit board, the plurality of electrodes are placed at a predetermined spacing. The spacing between the electrodes can be set as appropriate depending on the size or application of the circuit board, or the like.

The thickness of the circuit board is not particularly limited, and is preferably 3.0 mm or less, more preferably 2.0 mm or less, and still more preferably 1.0 mm or less, and preferably 0.1 mm or more, more preferably 0.2 mm or more, and still more preferably 0.5 mm or more. When the thickness of the circuit board is within the range described above, the thickness of the entire substrate for mounting can be reduced while maintaining strength.

### [Resin Layer]

In the resin layer, the plurality of openings for mounting on-board components are disposed on the electrodes of the circuit board. In the present invention, in a case in which each opening of the resin layer has a size of X μm in a longitudinal direction and Y μm in a lateral direction, and each on-board component has a size of x μm in a longitudinal direction and y μm in a lateral direction, the following conditions:

$$x + 20 < X < 2 x and y + 20 < Y < \sqrt{( {x}^{2} + {y}^{2} )}$$

are satisfied.

Further, the following conditions:

$$x + 20 < X < 1.6 x and y + 20 < Y < \sqrt{3} / 2 \times \{ \sqrt{( {x}^{2} + {y}^{2} )} \}$$

are preferably satisfied, and

$$x + 20 < X < 1.3 x and y + 20 < Y < \sqrt{2} / 2 \times \{ \sqrt{( {x}^{2} + {y}^{2} )} \}$$

are more preferably satisfied.

Even when the size of each on-board component is minute, poor connection caused by positional deviation is precluded by regulating the size of each opening of the resin layer and the size of each on-board component so that the sizes satisfy the conditions described above.

Each opening of the resin layer has a size of preferably 4.0 mm or less, more preferably 2.0 mm or less, and still more preferably 1.5 mm or less in a longitudinal direction, and preferably 3.0 mm or less, more preferably 2.0 mm or less, and still more preferably 1.5 mm or less in a lateral direction. A large number of openings can be disposed to enable a large number of on-board components to be mounted by allowing the size of each opening of the resin layer to satisfy the numerical range described above.

The shape of each opening of the resin layer, viewed from above, is not particularly limited. Examples thereof include: quadrangular shapes such as square, rectangular, and trapezoidal shapes; polygonal shapes; oval shapes; and circular shapes. Such quadrangular shapes are preferred. The quadrangular shapes may also be shapes with round corners (rounded-corner quadrangular shapes).

The thickness of the resin layer is preferably 1 μm or more, more preferably 5 μm or more, still more preferably 10 μm or more, and even more preferably 15 μm or more, and is preferably 60 μm or less, more preferably 50 μm or less, and still more preferably 40 μm or less. When the thickness of the resin layer is 1 μm or more, leakage of an anisotropically conductive connection material out of the openings is precluded in the case of coating the anisotropically conductive connection material into the openings. When the thickness of the resin layer is 60 μm or less, the deviations of the shapes of the openings from a design value are inhibited to inhibit occurrence of trouble in the case of disposing the openings.

### [Resin Composition]

The resin layer is formed of a cured product of a resin composition. The resin layer preferably has at least any one of a white color and a black color. The resin layer having a white color is preferred for enhancing the reflectivity of the resin layer, and the resin layer having a black color is preferred for preventing color mixture between neighboring LEDs to improve a contrast. Moreover, the resin layer is preferably a solder resist layer. The resin composition is not particularly limited, but preferably includes at least a resin and titanium oxide in the case of having a white color, and preferably includes at least a resin and a black pigment in the case of having a black color. Each component included in the resin composition is described below.

### (Resin)

As the resin, a curable resin such as a thermosetting resin or a photo-curable resin can be used without particular limitation, or a thermosetting resin and a photo-curable resin may also be used together.

Examples of the curable resin described above include curable resins having an epoxy group, an acryloyl group, a methacryloyl group, a hydroxy group, a vinyl group, a carboxy group, an amino group, a maleimide group, an acid anhydride group, a thiol group, a thionyl group, an amide group, an imido group, and the like as functional groups. Examples of such resins include a fluorine resin, an acryl resin, an amide resin, a polyimide resin, an isocyanate compound, a blocked isocyanate compound, an epoxy resin, an amino resin, a polyfunctional oxetane compound, a benzoxazine resin, a carbodiimide resin, a cyclocarbonate compound, an episulfide resin, a urethane resin, a polyester resin, a polyether resin, and a silicone resin. These resins may be used singly, or in combination of two or more kinds thereof.

### [Titanium Oxide]

Examples of titanium oxide include rutile type titanium oxide and anatase type titanium oxide. It is preferable to use rutile type titanium in the present invention. Anatase type titanium oxide which is the same kind of titanium oxide has higher whiteness than rutile type titanium oxide, and is commonly used as a white coloring agent. However, anatase type titanium oxide has photocatalyst activity, and may therefore cause discoloration of a resin in a resin layer due to light particularly irradiated from an LED. In contrast, rutile type titanium oxide is slightly inferior in whiteness to anatase type; however, the rutile type titanium oxide has almost no photoactivity, therefore results in prominently suppressed degradation (yellowing) of a resin by light due to the photoactivity of titanium oxide, and is also stable against heat. Therefore, a high reflectance can be maintained for a long period in a case in which the rutile type titanium oxide is used as a white coloring agent in the resin layer of a connecting structure in which LEDs are mounted.

Known rutile type titanium oxide can be used. Examples of methods of producing rutile type titanium oxide include two production methods which are a sulfuric acid method and a chlorine method. In the present invention, rutile type titanium oxide produced by any of the production methods can be preferably used. Here, the sulfuric acid method refers to a production method in which ilmenite ore or titanium slag as a raw material is dissolved in concentrated sulfuric acid to separate iron as ferrous sulfate, the solution is hydrolyzed to obtain a sediment of a hydroxide, and the sediment is burnt at high temperature to obtain rutile type titanium oxide. The chlorine method refers to a production method in which synthetic rutile or natural rutile as a raw material is allowed to react with chlorine gas and carbon at a high temperature of about 1000° C. to synthesize titanium tetrachloride, which is oxidized to obtain rutile type titanium oxide. Especially, rutile type titanium oxide produced by the chlorine method particularly prominently has an effect of suppressing the degradation (yellowing) of a resin due to heat, and is more preferably used in the present invention.

Titanium oxide of which the surface is treated with hydrous alumina, aluminum hydroxide, and/or a silicon dioxide may be used as the rutile type titanium oxide. Dispersibility in the resin composition, storage stability, flame resistance, and/or the like can be improved by using the surface-treated rutile type titanium oxide.

The average particle diameter of rutile type titanium oxide is preferably 0.1 μm or more and 1.0 μm or less, and more preferably 0.2 μm or more and 0.8 μm or less. In particular, 1% or more of rutile type titanium oxide having a particle diameter of 0.25 μm is preferably included with respect to the total of particles. Herein, the average particle diameter of rutile type titanium oxide is the average particle diameter (D50) which is the average of particle diameters including not only the particle diameters of primary particles but also the particle diameters of secondary particles (aggregates), and is a value of D50 measured by a laser diffraction method. Examples of measurement apparatuses used in the laser diffraction method include Microtrac MT3300EXII manufactured by MicrotracBEL Corp. The average particle diameter of titanium oxide refers to a value obtained by measuring a powder form prior to preparation (pre-stirring and kneading) of a curable resin composition, as described above.

Commercially available rutile type titanium oxide can also be used. For example, TIPAQUE R-820, TIPAQUE R-830, TIPAQUE R-930, TIPAQUE R-550, TIPAQUE R-630, TIPAQUE R-680, TIPAQUE R-670, TIPAQUE R-680, TIPAQUE R-670, TIPAQUE R-780, TIPAQUE R-850, TIPAQUE CR-50, TIPAQUE CR-57, TIPAQUE CR-80, TIPAQUE CR-90, TIPAQUE CR-90-2, TIPAQUE CR-93, TIPAQUE CR-95, TIPAQUE CR-97, TIPAQUE CR-63, TIPAQUE CR-58, and TIPAQUE UT771 (manufactured by ISHIHARA SANGYO KAISHA, LTD.), Ti-Pure R-101, Ti-Pure R-103, Ti-Pure R-104, Ti-Pure R-105, Ti-Pure R-108, Ti-Pure R-900, Ti-Pure R-902+, Ti-Pure R-960, and Ti-Pure R-706 (manufactured by DuPont de Nemours, Inc.), TITONE R-25, R-21, R-32, R-7E, R-5N, R-62N, R-42, R-45M, GTR-100, and D-918 (manufactured by SAKAI CHEMICAL INDUSTRY CO., LTD.), and the like can be used as commercially available rutile type titanium oxides.

In the present invention, the mass ratio of rutile type titanium oxide to the resin is 1.4 or more and 4 or less, preferably 1.8 or more and 3.5 or less, with respect to the resin on a solid content basis. In a case in which the mass ratio of rutile type titanium oxide to the resin is within the numerical range described above, the resin layer having a high reflectance can be obtained.

### [Black Pigment]

In the present invention, examples of the black pigment used in a case in which the resin layer is black include carbon black, perylene black, iron oxide, manganese dioxide, aniline black, and activated carbon, but are not limited thereto. It is preferable to include carbon black from the viewpoint of hiding power, solvent resistance, weather resistance, and heat resistance. In addition to carbon black, a pigment or dye that has a red, blue, green, or yellow color, or the like can also be mixed to achieve a black color or a black-based color similar to the black color.

### [Other Components]

### (Filler)

The mechanical strength of the resin layer can be improved by inclusion of a filler in the resin composition. The filler may be a known inorganic or organic filler that can be used as a filler that is used for an electronic material. Of these, inorganic fillers such as barium sulfate, silicas, Neuburg siliceous earth particles, and talc can be preferably used. Of these, silicas are preferred. A metal oxide and/or a metal hydroxide such as aluminum hydroxide may also be used together to obtain flame resistance. Such fillers may be used singly, or in combination of two or more kinds thereof.

Examples of silicas include fused silica, spherical silica, amorphous silica, crystalline silica, and pulverizing silica. Of these, spherical silica is preferred from the viewpoint of the flowability of the resin composition. The shape of the spherical silica may be a spherical shape, and is not limited to a true-spherical shape.

The average particle diameter of silica is 0.01 μm or more and 10 μm or less, preferably 0.05 μm or more and 5 μm or less. Herein, the average particle diameter of silica can be measured in a manner similar to that in the case of the average particle diameter of the titanium oxide described above.

As the silica, either silica that has not been surface-treated or surface-treated silica can be used. In the present invention, surface-treated silica is preferably used from the viewpoint of the flowability of the resin composition. In such surface treatment of silica, the silica may be blended in a state in which the silica has been surface-treated in advance, or surface-treated in a composition in which silica as an article that has not been surface-treated and a surface treatment agent are separately blended. The surface treatment agent is not particularly limited, a known surface treatment agent may be used, and a surface treatment agent having a curable reactive group, for example, a coupling agent having a curable reactive group as an organic group, or the like is preferably used.

A coupling agent based on silane, titanate, aluminate, zircoaluminate, or the like can be used as the coupling agent. Especially, a silane-based coupling agent is preferred. Examples of such silane-based coupling agents may include vinyltrimethoxysilane, vinyltriethoxysilane, N-(2-aminomethyl)-3-aminopropylmethyldimethoxysilane, N-(2-aminoethyl)-3-aminopropyltrimethoxysilane, 3-aminopropyltriethoxysilane, 3-anilinopropyltrimethoxysilane, 3-glycidoxypropyltrimethoxysilane, 3-glycidoxypropylmethyldimethoxysilane, 2-(3,4-epoxycyclohexyl)ethyltrimethoxysilane, 3-methacryloxypropyltrimethoxysilane, and 3-mercaptopropyltrimethoxysilane. These may be used singly, or in combination. The amount of such a treated silane-based coupling agent is preferably 0.5 to 10 parts by mass with respect to 100 parts by mass of silica. In the present invention, a reactive functional group derived from the coupling agent applied to the silica is not included in a compound having a photo-curable reactive group or a thermosetting functional group.

The amount of blended silica is preferably 1% by mass or more and 20% by mass or less, more preferably 2% by mass or more and 15% by mass or less, and still more preferably 3% by mass or more and 10% by mass or less in a solid content basis with respect to the resin composition. The amount of blended silica is within the range described above, whereby the reflectance of the resin layer can be improved. Silica is not particularly essential, and may be blended when an advantageous effect can be confirmed, for example, an effect of improving a reflectance is seen.

### (Heat-Curing Catalyst)

The resin composition can be blended with a heat-curing catalyst. Examples of the heat-curing catalyst include: imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; amine compounds such as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine; hydrazine compounds such as adipic acid dihydrazide and sebacic acid dihydrazide; and phosphorus compounds such as triphenyl phosphine. Examples of commercially available products thereof include: 2MZ-A, 2MZ-OK, 2PHZ, 2P4BHZ, and 2P4MHZ (all of which are the trade names of imidazole-based compounds) manufactured by SHIKOKU CHEMICALS CORPORATION; U-CAT 3513N (trade name of a dimethylamine-based compound) and DBU, DBN, and U-CAT SA 102 (all of which are bicyclic amidine compounds and salts thereof) manufactured by San-Apro Ltd. S-triazine derivatives such as, Guanamine, acetoguanamine, benzoguanamine, melamine, 2,4-diamino-6-methacryloyloxyethyl-S-triazine, 2-vinyl-2,4-diamino-S-triazine, 2-vinyl-4,6-diamino-S-triazine/isocyanuric acid adduct, and 2,4-diamino-6-methacryloyloxyethyl-S-triazine/isocyanuric acid adduct can also be used, and these compounds that also function as agents for imparting intimate contact properties are preferably used in combination with heat-curing catalysts. The heat-curing catalysts may be used singly, or in combination of two or more kinds thereof.

The amount of blended heat-curing catalyst is preferably 0.1 to 5 parts by mass, more preferably 1 to 3 parts by mass, on a solid content basis with respect to the total amount of the resin composition.

### (Organic Solvent)

The resin composition can be allowed to contain an organic solvent for the purpose of, for example, adjusting viscosity in the cases of preparing the composition and coating a substrate or a film. A known common organic solvent such as: a ketone such as methyl ethyl ketone or cyclohexanone; an aromatic hydrocarbon such as toluene, xylene, or tetramethylbenzene; a glycol ether such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylene glycol monomethyl ether acetate, or tripropylene glycol monomethyl ether; an ester such as ethyl acetate, butyl acetate, butyl lactate, cellosolve acetate, butyl cellosolve acetate, diethylene glycol monoethyl ether acetate, butyl carbitol acetate, propylene glycol monomethyl ether acetate, dipropylene glycol monomethyl ether acetate, or propylene carbonate; an aliphatic hydrocarbon such as octane or decane; or a petroleum-based solvent such as petroleum ether, petroleum naphtha, or solvent naphtha can be used as the organic solvent. Especially, esters are preferred, and diethylene glycol monoethyl ether acetate is more preferred, in view of resulting in the lower gloss level of a formed cured coating because oil absorption of the resin composition easily occurs in a silica surface in the case of curing and drying when a porous material such as amorphous silica is used. These organic solvents may be used singly, or in combination of two or more kinds thereof.

The amount of blended organic solvent is not particularly limited, and can be appropriately set according to viscosity of interest to allow easy preparation of the resin composition. The viscosity of the resin composition can be appropriately adjusted depending on a printing method and a printing plate. It is preferable that the viscosity is around 50 dPa·s to 800 dPa·s, preferably 100 dPa·s to 500 dPa·s, in the case of screen printing. The viscosity of the resin composition is within the range described above, whereby the deviations of openings from a design value are inhibited to inhibit occurrence of trouble when a large number of openings are disposed so that a large number of on-board components can be mounted in the connecting structure according to the present invention.

The resin composition can be further blended with a component such as a thixotropic agent, an intimate contact promoter, a block copolymer, a chain transfer agent, a polymerization inhibitor, a copper inhibitor, an antioxidant, an antirust agent, a thickener such as organic bentonite or montmorillonite, at least any one of defoamers and leveling agents based on silicone, fluorine, a polymer, or the like, a silane coupling agent based on imidazole, thiazole, triazole, or the like, or a flame retardant such as a phosphorus compound such as a phosphinate, a phosphate ester derivative, or a phosphazene compound, as needed, as well as the components described above. Components known in the field of electronic materials can be used as such components.

### [Method of Preparing Resin Composition]

For preparation of the resin composition, each component is weighed, blended, and then preliminarily stirred by a stirring machine. Subsequently, the preparation can be performed by dispersing and kneading each component by a kneading machine. Examples of the kneading machine described above may include bead mills, ball mills, sand mills, three-roll mills, and two-roll mills. A dispersion condition such as the speed ratio of each roll of such a three-roll mill can be appropriately set according to viscosity of interest.

### [Method of Producing Substrate for Mounting]

In a method of producing the substrate for mounting of the present invention, for example, the resin composition described above is coated on a circuit board on which a plurality of electrodes are placed at a predetermined spacing so that a plurality of openings are disposed in the upper regions of the electrodes, and is cured to form a resin layer.

A method of coating the resin composition is not particularly limited, and examples thereof include a screen printing method, a flow coating method, a roll coating method, a blade coating method, and a bar coating method. The resin composition may be adjusted to have a viscosity suitable for a coating method using the organic solvent described above.

A method of curing the resin composition is not particularly limited, but the resin composition is preferably heated at a temperature of 60 to 150° C. for 15 to 90 minutes. Examples of heating methods include a circulating type hot-air drying oven, an IR oven, a hot plate, and a convection oven (a method in which hot blast in a drying machine is subjected to countercurrent contact using an article including a heat source in an air heating manner by vapor, and a method in which the hot blast is sprayed on a support through a nozzle). For an apparatus, examples of the hot blast circulation drying oven include DF610 manufactured by Yamato Scientific Co., Ltd.

### [Connecting Structure]

The connecting structure according to the present invention includes: the above-described substrate for mounting; and an on-board component mounted in each opening of the substrate for mounting. In the connecting structure, the on-board component is preferably connected to each electrode of the substrate for mounting through a bonding member. The bonding member preferably allows the substrate for mounting and each on-board component to be electrically connected. Any of materials known in the art, such as an anisotropically conductive connection material, a conductive paste (solder, eutectic alloy, silver, gold, palladium, or the like), a bump, or a brazing filler material, can be used as the bonding member without particular limitation. Of these, an anisotropically conductive connection material is preferably used from the viewpoint of inhibiting a short circuit between electrodes and achieving high bonding strength.

### [On-Board Component]

Examples of such on-board components include surface mounted components such as LED chips such as mini-LEDs and μ-LEDs, chip-laminated ceramic capacitors, and chip resistors.

Each on-board component has a size of preferably 3.8 mm or less, more preferably 1.8 mm or less, and still more preferably 1.3 mm or less in a longitudinal direction, and preferably 2.8 mm or less, more preferably 1.8 mm or less, and still more preferably 1.3 mm or less in a lateral direction. The size of each on-board component satisfies the numerical range described above, whereby a large number of on-board components can be mounted on the substrate for mounting.

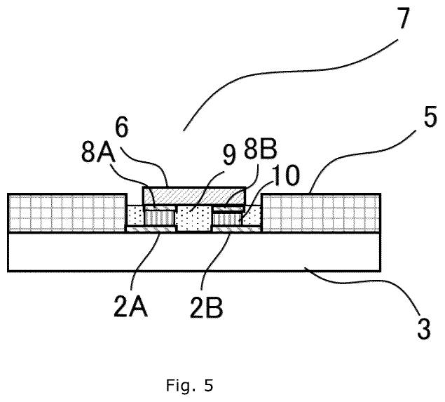

The connecting structure according to the present invention is described with reference to the drawings. The schematic top view of the connecting structure is described above. FIG. 5 illustrates a diagrammatic schematic cross-sectional view of one example of the connecting structure. In a connecting structure 7 illustrated in FIG. 5, electrodes 2 on a circuit board 3 and electrodes 8 on an on-board component 6 are connected to each other through solder 10 in an anisotropically conductive connection material 9.

### [Anisotropically Conductive Connection Material]

The anisotropically conductive connection material is an anisotropically conductive connection material in which conductive particles are homogeneously dispersed in a resin having adhesiveness. A conventionally known anisotropically conductive connection material can be used as the anisotropically conductive connection material without particular limitation. The anisotropically conductive connection material preferably comprises a thermosetting component (A), a polymerization initiator (B), and solder particles (C), and may further comprise a flux, a filler, a coupling agent, and the like.

The viscosity of the anisotropically conductive connection material at 25° C. is preferably 50 dPa·s or more and 3000 dPa·s or less, more preferably 100 dPa·s or more and 2500 dPa·s or less, and still more preferably 150 dPa·s or more and 2000 dPa·s or less. When the viscosity of the anisotropically conductive connection material at 25° C. is within the numerical range described above, coating of the anisotropically conductive connection material into the openings of the resin layer is facilitated.

The viscosity in the present invention refers to viscosity measured using a cone-plate type rotation viscometer (corn-plate type) (TVE-33H, rotor 3°×R9.7, manufactured by Toki Sangyo Co., Ltd.) under conditions of 25° C. and a rotor rotation speed of 5.0 rpm (shear rate of 10⁻¹ s) for 30 seconds according to JIS Z8803:2011 10 “Viscosity Measurement Method by Cone-Plate Type Rotation Viscometer”.

### (Thermosetting Component (A))

The thermosetting component described above is a compound that can be cured by heating. Examples of the thermosetting component described above include epoxy compounds, oxetane compounds, episulfide compounds, (meth)acrylic compounds, phenol compounds, amino compounds, unsaturated polyester compounds, polyurethane compounds, silicone compounds, and polyimide compounds. Epoxy compounds are preferred from the viewpoint of allowing the curability and viscosity of a conductive material to be more favorable and achieving still higher connection reliability.

Examples of the epoxy compounds include: epoxidized vegetable oils; bisphenol A type epoxy resins; hydroquinone type epoxy resins; bisphenol type epoxy resins; thioether type epoxy resins; brominated epoxy resins; novolac type epoxy resins; biphenol novolac type epoxy resins; bisphenol F type epoxy resins; hydrogenated bisphenol A type epoxy resins; glycidyl amine type epoxy resins; hydantoin type epoxy resins; alicyclic epoxy resins; trihydroxyphenyl methane type epoxy resins; bixylenol type or biphenol type epoxy resins or mixtures thereof; bisphenol S type epoxy resins; bisphenol A novolac type epoxy resins; tetraphenylol ethane type epoxy resins; heterocyclic epoxy resins; diglycidyl phthalate resins; tetraglycidyl xylenoyl ethane resins; epoxy resins containing naphthalene groups; epoxy resins having dicyclopentadiene skeletons; glycidyl methacrylate copolymer-based epoxy resins; copolymeric epoxy resins of cyclohexyl maleimide and glycidyl methacrylate; epoxy-modified polybutadiene rubber derivatives; and CTBN-modified epoxy resins. However, the epoxy compounds are not limited to thereto. The epoxy compounds may be used singly, or in combination of two or more kinds thereof.

Examples of the oxetane compounds include: polyfunctional oxetanes such as bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methylacrylate, (3-ethyl-3-oxetanyl)methylacrylate, (3-methyl-3-oxetanyl)methylmethacrylate, (3-ethyl-3-oxetanyl)methylmethacrylate, and oligomers or copolymers thereof; and etherified products of oxetane alcohols and resins having hydroxyl groups, such as novolac resins, poly(p-hydroxystyrene), cardo type bisphenols, calixarenes, calixresorcinarenes, and silsesquioxanes. Other examples thereof include copolymers of unsaturated monomers having oxetane rings and alkyl (meth)acrylates.

The amount of blended thermosetting component (A) in the anisotropically conductive connection material is preferably 10 to 95% by mass, more preferably 15 to 85% by mass, and still more preferably 20 to 80% by mass, on a solid content basis with respect to the total amount of the anisotropically conductive connection material.

### (Polymerization Initiator (B))

The polymerization initiator thermally cures the thermosetting component described above. Examples of the polymerization initiator include imidazole curing agents, amine curing agents, phenol curing agents, thiol curing agents such as polythiol curing agents, acid anhydrides, heat cationic initiators, heat cationic curing agents, and thermal radical generators. The polymerization initiators may be used singly, or in combination of two or more kinds thereof.

Especially, the polymerization initiator can still more immediately cure an anisotropically conductive connection material at a low temperature, and therefore, an imidazole curing agent, a thiol curing agent, or an amine curing agent is preferred, and an amine curing agent is more preferred. Moreover, a latent curing agent is preferred because storage stability is enhanced in the case of mixing the above-described thermoset agent and a curable compound that can be cured by heating. The latent curing agent is preferably a latent imidazole curing agent, a latent thiol curing agent, or a latent amine curing agent. The polymerization initiator may be covered with a high-molecular substance such as a polyurethane resin or a polyester resin.

The imidazole curing agent described above is not particularly limited, and examples thereof include 2-methylimidazole, 2-ethyl-4-methylimidazole, 1-cyanoethyl-2-phenylimidazole, 1-cyanoethyl-2-phenylimidazoliumtrimellitate, 2,4-diamino-6-[2′-methylimidazolyl-(1′)]-ethyl-s-triazine, and 2,4-diamino-6-[2′-methylimidazolyl-(1′)]-ethyl-s-triazine isocyanuric acid adducts.

The thiol curing agent described above is not particularly limited, and examples thereof include trimethylolpropanetris-3-mercaptopropionate, pentaerythritoltetrakis-3-mercaptopropionate, and dipentaerythritolhexa-3-mercaptopropionate.

The amine curing agent described above is not particularly limited, and examples thereof include dicyandiamide, hexamethylene diamine, octamethylene diamine, decamethylene diamine, 3,9-bis(3-aminopropyl)-2,4,8,10-tetraspiro[5.5]undecane, bis(4-aminocyclohexyl)methane, methaphenilene diamine, and diaminodiphenylsulphone.

Examples of the heat cationic initiator described above include iodonium-based cationic curing agents, oxonium-based cationic curing agents, and sulfonium-based cationic curing agents. Examples of the iodonium-based cationic curing agents described above include bis(4-tert-butylphenyl)iodoniumhexafluorophosphate. Examples of the oxonium-based cationic curing agents described above include trimethyloxonium tetrafluoroborate. Examples of the sulfonium-based cationic curing agents described above include tri-p-tolylsulfonium hexafluorophosphate.

The thermal radical generators described above are not particularly limited, and examples thereof include azo compounds and organic peroxides. Examples of the azo compounds described above include azobisisobutyronitrile (AIBN). Examples of the organic peroxides described above include di-tert-butyl peroxide and methyl ethyl ketone peroxide.

The amount of the polymerization initiator (B) in the anisotropically conductive connection material is preferably in a range of 0.1 to 25 parts by mass, more preferably 0.5 to 20 parts by mass, and still more preferably 1 to 20 parts by mass with respect to 100 parts by mass of the thermosetting component (A).

### (Solder Particles (C))

The anisotropically conductive connection material includes the solder particles (C), whereby the on-board components and the electrodes of the substrate for mounting can be electrically connected to each other.

Conventionally known solder particles can be used as the solder particles (C) without particular limitation, and in the present invention, low-melting-point solder particles are more preferred, and Sn—Pb-based low-melting-point solder particles and Sn—Bi-based low-melting-point solder particles are more preferred. Such low-melting-point solder particles mean solder particles having a melting point of 200° C. or less, preferably 170° C. or less, and more preferably 150° C. or less.

Moreover, solder particles that do not include lead are preferred as such low-melting-point solder particles. The solder particles that do not include lead mean solder particles having a lead content of 0.10% by mass or less. The lead content is defined in JIS Z 3282: 2017 (Soft solders-Chemical compositions and forms).

Low-melting-point solder particles including at least one or more metals selected from tin, bismuth, indium, copper, silver, and antimony are preferably used as the solder particles that do not include lead. In particular, an alloy of tin (Sn) and bismuth (Bi) is preferably used from the viewpoint of the balance of cost, handleability, and bonding strength.

The content of Bi in such low-melting-point solder particles is selected as appropriate in a range of 15 to 65% by mass, preferably 35 to 65% by mass, and more preferably 55 to 60% by mass.

A Bi content of 15% by mass or more causes an alloy of Bi to melt at a temperature starting from about 160° C. A further increase in the content of Bi results in a decrease in first melting temperature, a Bi content of 20% by mass or more results in a first melting temperature of 139° C., and a Bi content of 58% by mass results in eutectic composition. Accordingly, the effect of decreasing a melting point is sufficiently obtained by setting the content of Bi in a range of 15 to 65% by mass. As a result, sufficient conducting and connecting are achieved even at low temperature.

The solder particles (C) are preferably spherical. Here, the spherical solder particles refer to solder particles including 90% or more of solder particles of which the ratio of the major and minor diameters in a spherical powder is 1 to 1.5 at a magnification at which the shapes of solder particles can be observed.

Moreover, the solder particles (C) preferably have an average particle diameter of 1 to 100 μm, more preferably 2 to 80 μm, and still more preferably 3 to 60 μm. Herein, such an average particle diameter refers to a median diameter (D50) measured using a laser diffraction-type particle size meter.

Moreover, the amount of oxygen in the solder particles (C) is preferably 30 to 2000 ppm, more preferably 70 to 1400 ppm, and still more preferably 100 to 1000 ppm.

The amount of blended solder particles (C) in the anisotropically conductive connection material is preferably 5 to 90% by mass, more preferably 15 to 85% by mass, and particularly preferably 20 to 80% by mass, on a solid content basis with respect to the total amount of the anisotropically conductive connection material. Sufficient conducting and connecting can be secured by setting the amount of blended solder particles (C) at 5% by mass or more. Moreover, sufficient adhesiveness can be secured by setting the amount of blended solder particles at 90% by mass or less.

### (Other Components)

The anisotropically conductive connection material may include a flux as well as the solder particles (C). Examples of the flux include zinc chloride, mixtures of zinc chloride and inorganic halides, mixtures of zinc chloride and inorganic acids, molten salts, phosphoric acid, derivatives of phosphoric acid, organohalides, hydrazine, organic acids such as adipic acid, and rosin. Such fluxes may be used singly, or in combination of two or more kinds thereof.

The content of the flux in the anisotropically conductive connection material is preferably 1 to 30% by mass, and more preferably 1 to 20% by mass with respect to the amount of blended solder particles (C). Conducting and connecting properties can be still more improved by allowing the anisotropically conductive connection material to include the flux of which the content is within the range described above.

Moreover, the anisotropically conductive connection material may include a basic organic compound in order to adjust the activity of the flux. Examples of the basic organic compound include aniline hydrochloride and hydrazine hydrochloride.

Further, the anisotropically conductive connection material can be blended with a filler as needed in order to increase physical strength and the like in the case of curing. As the filler, a known inorganic or organic filler can be used, and in particular, barium sulfate, spherical silica, hydrotalcite, or talc is preferably used. Moreover, a metal oxide and/or a metal hydroxide such as aluminum hydroxide can be used as the filler in order to obtain flame resistance.

In the case of blending the filler, the filler may be surface-treated in order to enhance dispersibility in the anisotropically conductive connection material. Aggregation can be suppressed by using the surface-treated filler. A method of surface treatment is not particularly limited, a known common method may be used, and the surface of an inorganic filler is preferably treated with a surface treatment agent having a curable reactive group, for example, a coupling agent having a curable reactive group as an organic group, or the like.

A coupling agent based on silane, titanate, aluminate, zircoaluminate, or the like can be used as the coupling agent. Of these, a silane-based coupling agent is preferred. Examples of such silane-based coupling agents may include vinyltrimethoxysilane, vinyltriethoxysilane, N-(2-aminomethyl)-3-aminopropylmethyldimethoxysilane, N-(2-aminoethyl)-3-aminopropyltrimethoxysilane, 3-aminopropyltriethoxysilane, 3-anilinopropyltrimethoxysilane, 3-glycidoxypropyltrimethoxysilane, 3-glycidoxypropylmethyldimethoxysilane, 2-(3,4-epoxycyclohexyl)ethyltrimethoxysilane, 3-methacryloxypropyltrimethoxysilane, and 3-mercaptopropyltrimethoxysilane. These may be used singly, or in combination of two or more kinds thereof.

### (Additive)

The anisotropically conductive connection material can be blended with an additive such as a wet dispersant, a defoamer, or an agent for imparting a thixotropy property as needed, as well as with the components described above.

As such wet dispersants, known common wet dispersants can be used, and, for example, aliphatic carboxylic acids, aliphatic carboxylates, higher alcohol sulfate esters, alkyl sulfonic acids, phosphate esters, polyether, polyester-carboxylic acids, and salts thereof can be used. Of these, phosphate esters are preferred. The wet dispersants described above may be used singly, or in combination of two or more kinds thereof. The wet dispersant is included, whereby the solder particles are favorably dispersed, and the generation of coarse particles due to aggregation can be prevented.

The amount of blended wet dispersant is preferably 0.01 to 5% by mass, more preferably 0.05 to 3% by mass, and still more preferably 0.1 to 2% by mass on a solid content basis with respect to the total amount of the anisotropically conductive connection material from the viewpoint of the balance of coating film characteristics and the dispersibility of the solder particles.

As such defoamers, known common defoamers can be used, and, for example, silicone resins, modified silicone resins, organic high-molecular polymers, organic oligomers, and the like can be used. Of these, organic high-molecular polymers and organic oligomers are preferred. The defoamers described above may be used singly, or in combination of two or more kinds thereof. The defoamer is included, whereby generated bubbles can be removed, and therefore, bubbles remaining as voids in the thermosetting component(A) can be reduced when the thermosetting component (A) is solidified.

The amount of blended defoamer is preferably 0.01 to 10% by mass, more preferably 0.1 to 5% by mass, and still more preferably 0.5 to 3% by mass on a solid content basis with respect to the total amount of the anisotropically conductive connection material from the viewpoint of adhesiveness and the suppression of voids.

As such agents for imparting thixotropy properties, known common agents for imparting thixotropy properties can be used, and, for example, bentonite, wax, metal stearates, modified urea, and the like can be used. The agents for imparting thixotropy properties may be used singly, or in admixture of two or more kinds thereof. The agent for imparting a thixotropy property is included, whereby sedimentation of solder particles having a high specific gravity can be prevented.

The anisotropically conductive connection material may include a solvent. When the anisotropically conductive connection material includes the solvent, the content of the solvent is preferably 5% by mass or less with respect to the amount of solid in the anisotropically conductive connection material. Herein, “solvent” refers to, for example, an aromatic hydrocarbon, a glycol ether, an acetic ester, an alcohol, an aliphatic hydrocarbon, a petroleum-based solvent, or the like.

### [Method of Producing Connecting Structure]

The connecting structure according to the present invention can be produced by, for example, the following method.

First, the anisotropically conductive connection material described above is coated into the openings of the resin layer of the substrate for mounting of the present invention.

Then, the on-board components are mounted on the substrate for mounting through the anisotropically conductive connection material that has been coated, so that the electrodes of the substrate for mounting and the electrodes of the on-board components are positioned to face each other.

Subsequently, the substrate for mounting in a state in which the on-board components are mounted is heated to a temperature that is equal to or higher than the melting point of the solder particles (C) to melt the solder particles (C) and to wet both the electrodes with solder, and is cooled to solidify the solder and to further polymerize the thermosetting component (A), whereby the on-board component is fixed on the substrate for mounting.

### [Electronic Component]

An electronic component according to the present invention comprises the connecting structure described above. The electronic component with high quality and reliability can be provided by using the connecting structure of the present invention. In the present invention, the electronic component is not particularly limited, and examples thereof include mini-LED backlights for liquid crystal monitors and panels for p-LED displays.

### EXAMPLES

The present invention is described in more detail below with reference to Examples. However, the present invention is not limited to the following Examples.

### Synthesis of Fluorine Resin

A fluorine resin (copolymer of tetrafluoroethylene and vinyl acetate (molar ratio of tetrafluoroethylene and vinyl acetate=1/1)) was generated to obtain the fluorine resin having a hydroxyl value of 60 mg/g (KOH), by a known technique.

### Preparation of Resin Composition 1

Mixing of 25.5 parts by mass of the fluorine resin, synthesized as described above, 6.98 parts by mass of chain block diisocyanate (trade name: E402-B80B, manufactured by Asahi Kasei Corp.), 59.4 parts by mass of rutile type titanium oxide (having an average particle diameter of 0.28 μm, trade name: CR-93, manufactured by ISHIHARA SANGYO KAISHA, LTD.), and 7.0 parts by mass of silica (having an average particle diameter of 0.1 μm, trade name: Nipsil E743, manufactured by TOSOH SILICA CORPORATION) was performed, and the mixture was stirred by a stirring machine, and then kneaded by a three-roll mill. Subsequently, carbitol acetate was blended as an organic solvent to prepare a resin composition so that a solid content ratio was 78% by mass.

### Preparation of Anisotropically Conductive Connection Material 1

Preliminary mixing of 100 parts by mass of bisphenol A type epoxy resin (trade name: jER-828, manufactured by Mitsubishi Chemical Corporation), 5 parts by mass of dicyandiamide, and 10 parts by mass of adipic acid (manufactured by FUJIFILM Wako Pure Chemical Corporation) was performed by a stirring machine, and the mixture was then mixed and dispersed at room temperature by using a three-roll mill. Subsequently, 100 parts by mass of solder particles (manufactured by MITSUI MINING & SMELTING CO., LTD., spherical particles having 42Sn-58Bi composition, type 10-25, average particle diameter of 20.0 μm, melting point of 139° C., oxygen amount of 150 ppm) were blended, and mixed by a stirring machine to prepare an anisotropically conductive connection material 1.

For the anisotropically conductive connection material 1, a value measured using a corn-plate type viscometer (TV-33H, rotor 3°×R9.7, manufactured by Toki Sangyo Co., Ltd.) under conditions of 25° C. and a rotation speed of 5 rpm (shear rate of 10⁻¹ s) for 30 seconds according to JIS-Z8803:2011 was regarded as a viscosity. As a result of the measurement, the viscosity was 200 dPa·s.

### Preparation of Anisotropically Conductive Connection Material 2

Preliminary mixing of 50 parts by mass of bisphenol A type epoxy resin (trade name: jER-828, manufactured by Mitsubishi Chemical Corporation), 50 parts by mass of biphenyl type epoxy resin (trade name: YX-4000, manufactured by Mitsubishi Chemical Corporation), 5 parts by mass of dicyandiamide, and 10 parts by mass of adipic acid (manufactured by FUJIFILM Wako Pure Chemical Corporation) was performed by a stirring machine, and the mixture was then mixed and dispersed at room temperature by using a three-roll mill. Subsequently, 100 parts by mass of solder particles (manufactured by MITSUI MINING & SMELTING CO., LTD., spherical particles having 42Sn-58Bi composition, type 10-25, average particle diameter of 20.0 μm, melting point of 139° C., oxygen amount of 150 ppm) were blended, and mixed by a stirring machine to prepare an anisotropically conductive connection material 2.

As a result of measurement of the viscosity of the anisotropically conductive connection material 2 at 25° C. in a manner similar to that in the case of the anisotropically conductive connection material 1, the viscosity was 2000 dPa·s.

### Example 1

### Production of Substrate for Mounting

The resin composition was coated on a circuit board on which wiring and electrodes were formed by screen printing so that 288 openings were disposed in the upper regions of the electrodes. The resin composition was heated at 150° C. for 60 minutes to form a resin layer having a thickness of 30 μm to obtain a substrate for mounting. Each opening of the resin layer had a length (X) of 495 μm in the longitudinal direction and a length (Y) of 280 μm in the lateral direction.

### Production of Connecting Structure

Then, the anisotropically conductive connection material 1 was coated into the openings of the resin layer of the substrate for mounting through a metal mask (mask thickness: 100 μm, opening: 400 μm×200 μm) by a scraper so as to have a thickness of 80 μm. Then, an LED chip (having a length (x) of 400 μm in the longitudinal direction and a length (y) of 200 μm in the lateral direction, forward current: 15 mA) was aligned on the anisotropically conductive connection material 1 that had been coated by using a chip-mounting machine (ACT-1000, manufactured by ActesKyosan inc.) so that the electrodes of the LED chip and the electrodes of the substrate for mounting overlapped each other. The LED chip was mounted on the anisotropically conductive connection material 1 so that LEDs were put in the openings. Subsequently, the substrate for mounting was mounted on a hot plate (heating temperature: 180° C., digital hot plate ND-2A) in a state in which the LED chip was mounted. Heating was performed from an area closer to the substrate for mounting at 180° C. for 20 minutes to produce a connecting structure.

### Example 2

A connecting structure was produced in a manner similar to that in Example 1 except that the length (X) of each opening of the resin layer in the longitudinal direction was changed to 540 μm, and the length (Y) of each opening of the resin layer in the lateral direction was changed to 310 μm.

### Example 3

A connecting structure was produced in a manner similar to that in Example 1 except that the length (X) of each opening of the resin layer in the longitudinal direction was changed to 660 μm, and the length (Y) of each opening of the resin layer in the lateral direction was changed to 430 μm.

(Example 4) A connecting structure was produced in a manner similar to that in Example 1 except that the anisotropically conductive connection material 1 was changed to the anisotropically conductive connection material 2.

### Comparative Example 1

A connecting structure was produced in a manner similar to that in Example 1 except that the length (X) of each opening of the resin layer in the longitudinal direction was changed to 860 μm, and the length (Y) of each opening of the resin layer in the lateral direction was changed to 630 μm.

### Comparative Example 2

A connecting structure was produced in a manner similar to that in Example 1 except that the length (X) of each opening of the resin layer in the longitudinal direction was changed to 380 μm, and the length (Y) of each opening of the resin layer in the lateral direction was changed to 190 μm.

### Comparative Example 3

A connecting structure was produced in a manner similar to that in Example 1 except that the length (X) of each opening of the resin layer in the longitudinal direction was changed to 780 μm, and the length (Y) of each opening of the resin layer in the lateral direction was changed to 560 μm.

### [Evaluation of Connecting Structure]

### (Connection State)

A connection state caused by positional deviation in each connecting structure produced as described above was evaluated by the following method.

A forward current of 15 mA was applied to the electrode sections of each connecting structure by using a 7011DC signal source (HIOKI E.E. CORPORATION), and the acceptance or rejection of lighting of LEDs was confirmed. The acceptance or rejection of the lighting of the LEDs was evaluated based on the following criteria.

### (Evaluation Criteria)

Excellent: All the 288 LEDs mounted in the connecting structure were lighted.
Good: 230 or more of the 288 LEDs mounted in the connecting structure were lighted.
Poor: Less than 230 of the 288 LEDs mounted in the connecting structure were lighted.

Further, in a site in which LEDs that were not able to be lighted were mounted, the number of LEDs of which the impossible lightning was caused by poor connection due to positional deviation was measured. The evaluation results and the measurement results are set forth in Table 1.

In Comparative Example 2, the evaluation for acceptance or rejection of LED lighting was not performed because no LED was able to be mounted in any opening.

The connecting structures produced in Examples 1 to 4 and Comparative Examples 1 to 3 as described above are collectively set forth in the following Table 1.

TABLE 1

| | | Ex. 1 | Ex. 2 | Ex. 3 | Ex. 4 | Co. Ex. 1 | Co. Ex. 2 | Co. Ex. 3 |
|---|---|---|---|---|---|---|---|---|
| Kind of anisotropically conductive | | 1 | 1 | 1 | 2 | 1 | 1 | 1 |
| connection material | | | | | | | | |
| Length X (μm) of opening of resin | | 495 | 540 | 660 | 495 | 860 | 380 | 780 |
| layer in longitudinal direction | | | | | | | | |
| Length Y (μm) of opening of resin | | 280 | 310 | 430 | 280 | 630 | 190 | 560 |
| layer in lateral direction | | | | | | | | |
| Length x (μm) of on-board | | 400 | 400 | 400 | 400 | 400 | 400 | 400 |
| component in longitudinal direction | | | | | | | | |
| Length y (μm) of on-board | | 200 | 200 | 200 | 200 | 200 | 200 | 200 |
| component in lateral direction | | | | | | | | |
| Range of X | x + 20 | 420 | 420 | 420 | 420 | 420 | 420 | 420 |
| | 2x | 800 | 800 | 800 | 800 | 800 | 800 | 800 |
| Range of Y | Y + 20 | 220 | 220 | 220 | 220 | 220 | 220 | 220 |
| | √(x2 + y2) | 447 | 447 | 447 | 447 | 447 | 447 | 447 |

| | | | | | | | |
|---|---|---|---|---|---|---|---|
| Viscosity (dPa · s) of anisotropically | 200 | 200 | 200 | 2000 | 200 | 200 | 200 |
| conductive connection material | | | | | | | |
| Acceptance or rejection of LED | Excellent | Excellent | Good | Excellent | Poor | — | Poor |
| lighting | | | | | | | |
| Positional deviation sites/poor | — | — | 30/30 | — | 60/63 | — | 54/55 |
| lighting sites | | | | | | | |

### REFERENCE SIGNS LIST

1: Substrate for mounting
2A: Positive electrode of substrate
2B: Negative electrode of substrate
3: Circuit board
4: Opening
5: Resin layer
6: On-board component
7: Connecting structure
8A: Positive electrode of on-board component
8B: Negative electrode of on-board component
9: Anisotropically conductive connection material
10: Solder
X: Length of opening in longitudinal direction
Y: Length of opening in lateral direction
x: Length of on-board component in longitudinal direction
y: Length of on-board component in lateral direction

1. A substrate for mounting an on-board component, the substrate for mounting, comprising a circuit board on which a plurality of electrodes are placed at a predetermined spacing, and a resin layer comprising a plurality of openings in upper regions of the electrodes of the circuit board, wherein
in a case in which each opening of the resin layer has a size of X μm in a longitudinal direction and Y μm in a lateral direction, and the on-board component has a size of x μm in a longitudinal direction and y μm in a lateral direction, the following conditions:
$$x + 20 < X < 2 x and y + 20 < Y < \sqrt{( x 2 + y 2 )}$$
are satisfied.

2. The substrate for mounting according to claim 1, wherein the resin layer has a thickness of 1 μm or more and 60 μm or less.

3. The substrate for mounting according to claim 1, wherein the resin layer has at least any one of a white color and a black color.

4. The substrate for mounting according to claim 1, wherein the resin layer is a solder resist layer.

5. The substrate for mounting according to claim 1, wherein the on-board component is an LED.

6. A connecting structure comprising:
the substrate for mounting according to claim 1; and
the on-board component that is mounted in each opening of the substrate for mounting.

7. The connecting structure according to claim 6, wherein the on-board component and the electrodes of the substrate for mounting are connected to each other through an anisotropically conductive connection material.

8. The connecting structure according to claim 7, wherein the anisotropically conductive connection material comprises a thermosetting component (A), a polymerization initiator (B), and a solder particle (C).

9. The connecting structure according to claim 8, wherein the anisotropically conductive connection material has a viscosity of 50 dPa·s or more and 3000 dPa·s or less at 25° C.

10. An electronic component comprising the connecting structure according to claim 6.
